(19) United States
(12) Patent Application Publication
(10) Pub. No.: US 2006/0029830 A1
(43) Pub. Date: Feb. 9, 2006

(54) NbSi-2 base nanocomposite coating and manufacturing method thereof

(75) Inventors: Jin-Kook Yoon, Seoul (KR); Gyeung-Ho Kim, Seoul (KR); Kyung-Tae Hong, Seoul (KR); Jung-Man Doh, Seoul (KR); Jong-Kwon Lee, Seoul (KR); Kyung-Hwan Lee, Seoul (KR); Keun-Hyung Son, Seoul (KR)

Correspondence Address: MORRISON & FOERSTER LLP, 1650 TYSONS BOULEVARD, SUITE 300, MCLEAN, VA, 22102, US

(73) Assignee: Korea Institute of Science and Technology, Seoul (KR)

(21) Appl. No.: 11/023,463

(22) Filed: Dec. 29, 2004

(30) Foreign Application Priority Data
Aug. 5, 2004 (KR) 61786/2004

(51) Int. Cl. B32B 19/00; B32B 9/00; C23C 16/26

(52) U.S. Cl. 428/697; 428/698; 427/402; 427/249.1

(57) ABSTRACT

A NbSi₂-base nanocomposite coating formed on the surface of niobium or niobium-base alloys is disclosed. The nanocomposite coating layer is manufactured by forming a niobium carbide layers or a niobium nitride layers by depositing of carbon or nitrogen on the surface, and then depositing silicon. The nanocomposite coating layer has a microstructure that SiC or Si₃N₄ particles are mostly precipitated on an equiaxed NbSi₂ grain boundary. The thermal expansion coefficients of NbSi₂-base nanocomposite coating layers become close to that of the substrates by adjusting the volume fraction of SiC or Si₃N₄ particles in the nanocomposite coating layers. Accordingly, the generation of cracks caused by thermal stress due to the mismatch in thermal expansion coefficient between the NbSi₂-base nanocomposite coatings and the substrates can be suppressed, thereby improving the high-temperature oxidation resistance in the repeated thermal cycling use of the NbSi₂-base nanocomposite coated substrates. Further, the increase in the volume fraction of dense SiO₂ oxide phase formed on the surface of the NbSi₂-base nanocomposite coating layers improves also high-temperature isothermal oxidation resistance.

### BACKGROUND OF THE INVENTION

1. Field of the Invention

The present invention relates to an NbSi₂-base nanocomposite coating on niobium or niobium-base alloys with excellent oxidation resistance and corrosion resistance, and a manufacturing method thereof.

2. Description of the Background Art

Niobium and niobium-base alloys have been used as core material in the fields of aerospace, atomic energy, etc. since they have a low density (8.55 g/cm³) and excellent mechanical and thermal properties at high temperature. However, they react with oxygen at high temperature to form the oxide scale of Nb₂O₅. Since the diffusivity of oxygen in the Nb₂O₅ phase is relatively high, Nb₂O₅ cannot be used as a protective oxide scale for niobium. Therefore, niobium and niobium-base alloys are only used for very limited condition under vacuum, reductive or inert atmosphere.

When an alloying element is added to niobium and niobium-base alloys in order to improve their high-temperature oxidation resistance, the high-temperature mechanical properties thereof are deteriorated. Due to the reason as above, niobium-base alloys with both oxidation resistance and mechanical properties at high temperature has not been developed yet. Therefore, a niobium substrate coated with an excellent high-temperature oxidation resistant material has been widely proposed.

After the NbSi₂ modified with Cr and Fe was developed as a coating material for niobium, many researchers have been studied to develop a new coating material with excellent high-temperature oxidation resistance.

Coating material for providing niobium with high-temperature oxidation resistance should be capable to form a dense oxide scale when exposed to an oxidation atmosphere at high temperature. High-temperature stable oxide at over 1000° C. is for example Al₂O₃ and SiO₂. Thus, niobium aluminides and niobium suicides have been developed as a protection layer on niobium or niobium-base alloys. However, as niobium-base alloys are required to be used at higher temperature, the improvement of oxidation resistance of niobium silicide coating layer has been mainly studied and the researches have been concentrated on solving the following two main problems.

First, when NbSi₂ coating layer is exposed to oxidizing atmosphere, NbSi₂ reacts with oxygen to form a mixed oxide layer consisting of Nb₂O₅ and SiO₂. The diffusivity of oxygen in the Nb₂O₅ phase is relatively high. Therefore, although NbSi₂ could be eventually protected by a thick mixed-oxide layer, spallation problems due to growth stresses become critical as scale thickness increases, and the oxide scale on NbSi₂ cracks extensively.

Secondly, when NbSi₂ coating layer manufactured at high temperature or used at high temperature is cooled at room temperature, many cracks are generated within the coating layer due to the mismatch in the thermal expansion coefficient between the substrate and the coating layer. Thus, the repeated thermal cyclic oxidation between high temperature and room temperature deteriorates the oxidation resistance of the coating layer.

Accordingly, there is a demand for the development of a new coating layer capable of solving the above problems.

### SUMMARY OF THE INVENTION

Therefore, an object of the present invention is to provide a new nanocomposite coating on the surface of niobium or niobium-base alloys with excellent oxidation resistance and corrosion resistance at high temperature and with enhanced high-temperature mechanical properties.

To achieve these and other advantages and in accordance with the purpose of the present invention, as embodied and broadly described herein, there is provided the NbSi₂-base nanocomposite coating on the surface of niobium or niobium alloy as a substrate. The NbSi₂-base nanocomposite coating layer has a microstructure that SiC or Si₃N₄ particles are mostly located on an equiaxed NbSi₂ grain boundary. In the coating layer, the average size of NbSi₂ grains ranges from 44 to 135 nm, and SiC and Si₃N₄ particles have the average particle size from 33 to 60 nm. The NbSi₂-base nanocomposite coating layer has a thermal expansion coefficient close to that of the substrate by controlling the volume fraction of SiC or Si₃N₄ particles in the NbSi₂-base nanocomposite coating.

The niobium-base alloys used as the substrate include Nb-19Ti-4Hf-13Cr-2Al-4B-16Si, Nb-10Si-9Al-10Ti, Nb-5Mo-1Zr, Nb-5Mo-2W-18Si, etc. and are not limited thereto, but other various niobium alloys can be used.

Further, the present invention provides a manufacturing method of an NbSi₂—SiC nanocomposite coating layer. The method comprises the steps of: forming a niobium carbide diffusion layers (NbC and Nb₂C) by depositing carbon on the surface of niobium or niobium-base alloys; and forming a NbSi₂—SiC nanocomposite coating layer by depositing silicon on the surface of the niobium carbide diffusion layers.

Furthermore, the present invention provides a manufacturing method of an NbSi₂—Si₃N₄ nanocomposite coating layer. The method comprises the steps of: forming a niobium nitride diffusion layers (NbN, NbN₃ and Nb₂N) by depositing nitrogen on the surface of niobium or niobium-base alloys; and forming a NbSi₂—Si₃N₄ nanocomposite coating layer by depositing silicon on the surface of the niobium nitride diffusion layers.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is an optical micrograph of a cross-section of a NbSi₂ coating layer having a typical columnar microstructure manufactured on a niobium surface by conventional reactive diffusion method;

FIG. 2 is an optical micrograph of a cross-section of a NbSi₂—SiC nanocomposite coating layer formed on the surface of niobium according to Example 1 of the present invention;

FIG. 3 is an optical micrograph of a cross-section of a NbSi₂—Si₃N₄ nanocomposite coating layer formed on the surface of niobium according to Example 3 of the present invention; and

FIG. 4 is a graph of the comparison in isothermal oxidation resistance between the nanocomposite coatings of Examples 1 and 2 of the present invention and the monolithic NbSi₂ coating made by conventional reactive diffusion in 80% Ar-20% O₂ atmosphere at 1100° C. atmosphere.

### DETAILED DESCRIPTION OF THE PREFERRED EMBODIMENTS

Hereinafter, NbSi₂-base nanocomposite coating layer and manufacturing methods thereof according to the preset invention will be described in detail.

In accordance with the present invention, the NbSi₂-base nanocomposite coating layer on the surface of niobium or niobium-base alloys has a microstructure that SiC or Si₃N₄ particles are mostly located on an equiaxed grain boundaries of NbSi₂.

In the nanocomposite coating layer, the morphology of NbSi₂ grains is the equiaxed type. The thermal expansion coefficient of the NbSi₂-base nanocomposite coating layers can be close to that of a substrate (niobium or niobium-base alloys) by controlling the volume fraction of SiC or Si₃N₄ particles in the nanocomposite coating layers. As a result, when the coating layer manufactured at high temperature is then cooled to room temperature, or even if the coating layer is used repetitively between high temperature and room temperature, it is possible to reduce or eliminate the generation of fine cracks caused by a thermal stress due to the mismatch in the thermal expansion coefficient between the substrate and the coating layer.

The SiC or Si₃N₄ particles in the NbSi₂-base nanocomposite coating layers are preferentially formed on NbSi₂ grain boundaries due to their solubility limit in the NbSi₂.

Further, the SiC and Si₃N₄ particles (thermal expansion coefficients of about 4×10⁻⁶/° C. and 2.9×10⁻⁶/° C., respectively) are made composite with pure NbSi₂ (thermal expansion coefficient of about 11.7×10⁻⁶/° C.) so as to have a thermal expansion coefficient close to that of the substrate, whereby the generation of fine cracks is suppressed and the high-temperature oxidation resistance of the coatings is enhanced.

Moreover, if oxygen is diffused through the NbSi₂ grain boundaries under the oxidative atmosphere, the SiC and Si₃N₄ particles easily form a SiO₂ protective scale, thereby making it difficult for oxygen to further diffuse inside through the NbSi₂ crystal grain boundary. This makes the low-temperature oxidation resistance of the NbSi₂-base nanocomposite coating layer far superior to that of monolithic NbSi₂ coating layer. Such a microstructural feature of the NbSi₂-base nanocomposite coating layer makes it possible to efficiently suppress the diffusion of oxygen through the NbSi₂ grain boundary even by a relatively small amount of SiC and Si₃N₄ particles in comparison with an NbSi₂—Si₃N₄ or NbSi₂—SiC sintered composites.

In addition, the SiC and Si₃N₄ particles play the role of suppressing the growth of NbSi₂ grains to prevent mechanical properties of the coating layer from being deteriorated due to grain coarsening.

Manufacture of NbSi₂—SiC Nanocomposite Coating Layer

Firstly, carbon is vapor-deposited on the surface of a niobium or niobium-base alloy substrates at high temperature under a high purity argon atmosphere by chemical vapor deposition. Carbon monoxide (CO), methane (CH₄), ethane (C₂H₄) or methylene iodide (CH₂I₂) can be used as a carbon source.

In this case, the carbon deposited on the surface of the substrate chemically reacts with the substrate to form the niobium carbide diffusion layers (NbC and Nb₂C). As the deposition time increases, the carbon deposited on the surface of the substrate inwardly diffuse to the interface between niobium carbide and the niobium substrate through the niobium carbide diffusion layers and then reacts with a new niobium to continuously form a niobium carbide diffusion layers.

After a niobium carbide diffusion layers with a predetermined thickness is formed on the surface of the substrate, silicon is then vapor-deposited for a predetermined time by chemical vapor deposition using SiCl₄, SiH₂Cl₂, SiH₃Cl or SiH₄. In this case, silicon can be vapor-deposited by the pack siliconizing method in which uses pack siliconizing powders composed of (1-70) wt % Si/(1-10) wt % NaF/(20-98) wt Al₂O₃.

If the deposited silicon is reactively diffused into the niobium carbide diffusion layers, the NbSi₂ and SiC phases are formed by the solid-state displacement reaction as shown in the following reaction formulas (a) and (b):
Nb₂C+5Si→2NbSi₂+SiC (a)
NbC+3Si→NbSi₂+SiC (b)

Since the solubility of carbon in NbSi₂ phase is very low, SiC particles formed by the chemical reaction according to the formulas (a) and (b) are mainly precipitated on the NbSi₂ grain boundary.

The silicon deposited on the surface of the substrate continues to diffuse inwardly through a NbSi₂—SiC nanocomposite coating layer and reacts with the niobium carbide diffusion layers to form new NbSi₂ and SiC particles. Accordingly, the NbSi₂—SiC nanocomposite coating layers with a thickness of several tens to several hundreds of micrometers can be obtained.

In case of manufacturing a NbSi₂—SiC nanocomposite coating layer by the chemical reaction formula (a), the theoretical volume fraction of SiC particles is calculated by using the molar volumes of NbSi₂ (26.61 cm³/mol) and SiC (12.61 cm³/mol) as follows:
SiC vol %=[12.61/(12.61+2×26.61)]×100=19.2%

The experimental volume fraction of SiC particles is about 17.3%.

On the other hand, in case of manufacturing an NbSi₂—SiC nanocomposite coating layer by the chemical reaction formula (b), the theoretical volume fraction of SiC particles is calculated as follows:
SiC vol %=[12.61/(12.61+26.61)]×100=32.3%

The experimental volume fraction of SiC particles is about 31.1%.

Consequently, in case that a NbSi₂—SiC nanocomposite coating layer is manufactured using a niobium carbide diffusion layers, the volume fraction of SiC phase existing in the nanocomposite coating layer is adjustable according to the concentration of carbon existing in the niobium carbide layers. Thus it becomes possible to make the thermal expansion coefficients of the nanocomposite coating layer coincident with that of the substrate. Accordingly, upon cooling from high temperature to low temperature, the amount of cracks formed by the thermal stress generated due to the mismatch in the thermal expansion coefficient difference can be adjusted. In some cases, it is possible to manufacture a NbSi₂—SiC nanocomposite coating layer with no crack at all.

Manufacture of NbSi₂—Si₃N₄ Nanocomposite Coating Layer

Firstly, nitrogen is vapor-deposited on the surface of a niobium or niobium-base alloy substrate at high temperature under a high purity argon atmosphere by chemical vapor deposition. Nitrogen (N₂) and ammonia (NH₃) gases can be used as a nitrogen source.

In this case, the nitrogen deposited on the surface of the substrate chemically reacts with the substrate to form a niobium nitride-diffusion layers (NbN, Nb₄N₃ and Nb₂N). As the deposition time increases, the nitrogen deposited on the surface of the substrate diffuse inwardly to the interface between niobium nitride layers and niobium substrate through the niobium nitride diffusion layers and then reacts with a new niobium to continuously form a niobium nitride diffusion layers.

After a niobium nitride diffusion layers with a predetermined thickness is formed on the surface of the substrate, silicon is then vapor-deposited for a predetermined time by chemical vapor deposition using SiCl₄, SiH₂Cl₂, SiH₃Cl or SiH₄.

Also in this case, silicon can be vapor-deposited by the pack siliconizing method using pack siliconizing powders composed of (1-70) wt % Si/(1-10) wt % NaF/(20-98) wt Al₂O₃.

If the deposited silicon is reactively diffused into the niobium nitride diffusion layers, the NbSi₂ and Si₃N₄ phases are formed by the solid-state displacement reactions as shown in the following reaction formulas (c), (d) and (e):
4Nb₂N+19Si→8NbSi₂+Si₃N₄ (c)
4Nb₄N₃+41Si→16NbSi₂+3Si₃N₄ (d)
4NbN+11Si→4NbSi₂+Si₃N₄ (e)

Since the solubility of nitrogen in NbSi₂ phase is very low, Si₃N₄ particles formed by the chemical reaction formulas (c), (d), and (e) are mainly formed on the NbSi₂ grain boundary.

The silicon deposited on the surface of the substrate continues to diffuse inwardly through an NbSi₂—Si₃N₄ nanocomposite coating layer and reacts with the niobium nitride diffusion layers to form new NbSi₂ phase and Si₃N₄ particles. Accordingly, a NbSi₂—Si₃N₄ nanocomposite coating with a thickness of several tens to several hundreds of micrometers can be obtained.

In case of manufacturing a NbSi₂—Si₃N₄ nanocomposite coating layer by the chemical reaction formula (c), the theoretical volume fraction of Si₃N₄ particles is calculated by the molar volumes of NbSi₂ (26.61 cm³/mol) and Si₃N₄ (44.3 cm³/mol) as follows:
Si₃N₄ vol %=[44.3/(8×26.61+44.3)]×100=17.2%

The experimental volume fraction of Si₃N₄ particles is about 16.8%.

On the other hand, in case of manufacturing a NbSi₂—Si₃N₄ nanocomposite coating layer by the chemical reaction formula (d), the volume fraction of theoretically formable Si₃N₄ particles is calculated as follows:
Si₃N₄ vol %=[3×44.3/(16×26.61+3×44.3)]×100=23.8%.

In addition, in case of manufacturing a NbSi₂—Si₃N₄ nanocomposite coating layer by the chemical reaction formula (e), the volume fraction of theoretically formable Si₃N₄ particles is calculated as follows:
Si₃N₄ vol %=[44.3/(4×26.61+44.3)]×100=29.4%.

The experimental volume fraction of Si₃N₄ particles is about 24.4%, which is in the range of theoretical volume percentage calculated by the chemical reaction formula (d) and, (e) since the outer layer of NbSi₂—Si₃N₄ nanocomposite coating is composed of the Nb₄N₃ and NbN phases.

Consequently, in case that a NbSi₂—Si₃N₄ nanocomposite coating layer is manufactured using a niobium nitride diffusion layers, the volume fraction of Si₃N₄ phase existing in the nanocomposite coating is adjustable according to the concentration of nitrogen existing in the niobium nitride layers. Thus it becomes possible to make the thermal expansion coefficients of the nanocomposite coatings coincident with that of the respective substrate materials. Accordingly, upon cooling from high temperature to low temperature, the amount of cracks formed by a thermal stress generated due to the mismatch in the thermal expansion coefficient between the nanocomposite coatings and the substrates can be adjusted. In some cases, it is possible to manufacture a NbSi₂—Si₃N₄ nanocomposite coating with no crack at all.

### EXAMPLE 1

Nb with a purity of 99.95% and a size of 10 mm×10 mm×1 mm was prepared. Nb metal plates (99.95% purity) were cut into pieces of 10 mm×10 mm×1 mm and then polished successively using SiC papers and 1 μm diamond paste. The polished pieces were ultrasonically cleaned in acetone, alcohol, distilled water, and then dried.

The pretreated niobium was put into a high purity alumina reaction tube capable of chemical vapor deposition of carbon, a high purity argon gas (99.9999%) was blown thereto to remove oxygen in the reaction tube, heated up to 800 to 1500° C. at a heating speed of 5 to 20° C./min while flowing a high purity argon gas at a flow rate of 100 to 2,000 cm/min, then preserved for about 10 to 20 minutes in order to stabilize a deposition temperature, and then carbon was deposited on the niobium surface for 10 minutes to 200 hours while supplying a methane gas and a hydrogen gas at a flow rate of 3 to 2,000 cm/min respectively.

The carbon deposited on the surface of the substrate chemically reacted with niobium to form two diffusion layers composed of NbC and Nb₂C respectively. As the deposition time increases, the carbon deposited on the niobium metal surface diffused to the niobium carbide/niobium interface through the niobium carbide diffusion layer and then reacted with a new niobium to form the niobium carbide diffusion layers in proportion to the square root of the deposition time.

It is possible to kinetically calculate the deposition temperature and time for making a niobium carbide diffusion layers of a predetermined thickness. As an example, if carbon is chemical vapor-deposited for about 10 hours at a deposition temperature of 1400° C., a Nb₂C diffusion layer having a thickness of approximately 4 μm and a NbC diffusion layer having a thickness of approximately 14 μm grows on the niobium metal surface.

After manufacturing a niobium carbide diffusion layers with a predetermined thickness, the supplying of methane gas was stopped, the niobium carbide diffusion layers was cooled up to 1100° C. at a cooling rate of 5° C./mm while supplying a high purity argon gas into the reaction tube at a flow rate of 30 to 3,000 cm/min, and then silicon was chemical vapor-deposited on the surface of the niobium carbide diffusion layers for 30 minutes to 30 hours while supplying a silicon tetrachloride (SiCl₄) gas and hydrogen into the reaction tube, with the flow ratio thereof set to about 0.005 to 0.5 and the total flow set to about 30 to 4,000 cm/min.

The deposited silicon formed an NbSi₂ phase and a SiC phase by a solid-state displacement reaction with a niobium carbide phase. As the deposition time increases, the deposited silicon continued to diffuse inwardly through a NbSi₂—SiC nanocomposite coating and reacts with the niobium carbide diffusion layers to form new NbSi₂ phase and SiC particles, thereby manufacturing a NbSi₂—SiC nanocomposite coating layer.

The thickness of the NbSi₂—SiC nanocomposite coating layer grows in proportion to the square root of a chemical vapor deposition time of silicon. Accordingly, it is possible to kinetically calculate the deposition temperature and time for making a NbSi₂—SiC nanocomposite coating layer of a predetermined thickness. As an example, silicon is chemical vapor-deposited on the surface of the niobium carbide diffusion layers for 1.5 hours at a deposition temperature of 1100° C. and reactively diffused into the niobium carbide diffusion layers, thereby manufacturing a Nb₂C—SiC nonocomposite coating layer having a thickness of 50 μm and excellent in oxidation resistance and corrosion resistance.

After the manufacture of the nanocomposite coating layer, it was furnace-cooled while flowing a high purity argon gas at a flow rate of 100 to 2,000 cm/min.

Hydrogen and silicon tetrachloride gas used in Example 1 were a high purity gas used in the field of semiconductor. Since silicon tetrachloride gas has a evaporation temperature of about 54° C., in this example, a silicon tetrachloride solution was injected into a bubbler kept at a constant temperature of 0 to 30° C., and then bubbled using a hydrogen gas to be supplied into the reaction tube. In this example, the chemical vapor deposition was carried out in a tubular furnace with a reaction tube made of a high purity quartz tube having an inner diameter of about 20 mm.

### EXAMPLE 2

A niobium substrate coated with a niobium carbide diffusion layers of a predetermined thickness was buried in a mixed powders composed of (1-70) wt % Si/(1-10) wt % NaF/(20-98) wt Al₂O₃ and then was put into a pack siliconizing reaction tube.

A high purity argon gas was blown to remove oxygen in the reaction tube, heated up to 800 to 1500° C. at a heating speed of 5 to 20° C./min while flowing a high purity argon gas at a flow rate of 100 to 2,000 cm/min, then preserved for about 30 minutes to 30 hours, and then silicon is chemically vapor-deposited on the metal surface to be reactively diffused into the niobium carbide diffusion layers.

After manufacturing a NbSi₂—SiC nanocomposite coating layer on the metal surface, it was furnace-cooled up to a room temperature while flowing a high purity argon gas at a flow rate of 100 to 2,000 cm/min.

The thickness of the NbSi₂—SiC nanocomposite coating layer manufactured by pack siliconizing process, as in chemical deposition, increases in proportion to the square root of silicon deposition time. Thus, it is possible to kinetically predict deposition temperature and time for manufacturing a nanocomposite coating with a predetermined thickness.

As for the powders for pack siliconizing treatment, a powder composed of (1-70) wt % Si/(1-10) wt % NaF/(20-98) wt Al₂O₃ was measured up to 50 g and then mixed for 24 hours using a mixer moving rotationally and vertically. The used silicon powder had a purity of 99.5% and an average particle size of 44 μm, the active agent was NaF of reagent level, and the filling agent was a high purity alumina with an average size of 44 μm.

The pack siliconizing treatment was carried out in a reaction tube (Inconel 600) with an inside diameter of 60 mm at a temperature below 1100° C., and in a high purity alumina tube at a temperature over 1200° C. The mixed powders for pack siliconizing treatement was filled in an alumina crucible, and niobium metals coated with a niobium carbide diffusion layers was buried into the middle thereof and then enclosed with an alumina cover.

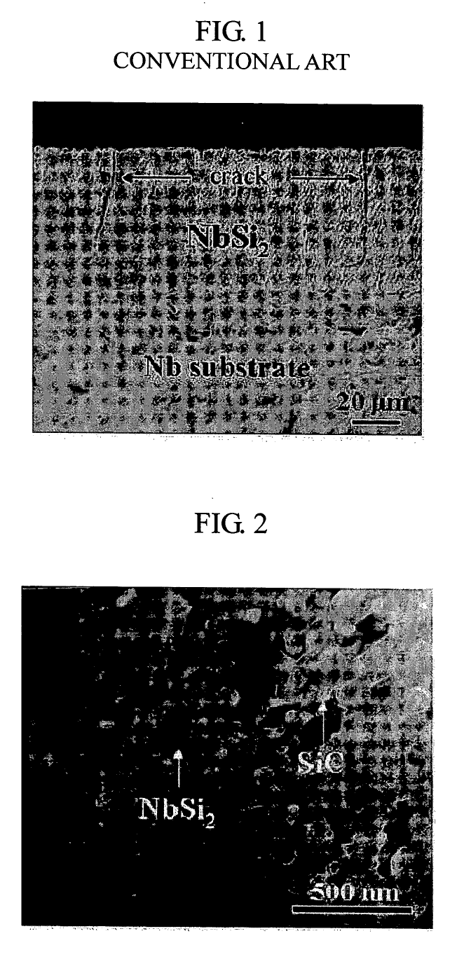

FIG. 1 is an optical micrograph of the cross-section of an NbSi₂ coating layer having a columnar structure manufactured by a conventional reactive diffusion processes such as chemical vapor deposition, pack siliconizing process, solution growth into molten Si—In alloy. FIG. 2 is a cross-sectional transmission electron image of a NbSi₂—SiC nanocomposite coating manufactured according to Example 1 of the present invention.

NbSi₂—SiC nanocomposite coating manufactured in Example 1 of the present invention is compared to the conventional NbSi₂ coating layer manufactured by depositing silicon on a niobium substrate by chemical vapor deposition, as follows.

The NbSi₂—SiC nanocomposite coating layers manufactured according to Example 1 of the present invention, as shown in FIG. 2, has ultrafine SiC particles formed on an equiaxed NbSi₂ grain boundary. As measured by image analyzer, the average size of equiaxed NbSi₂ grains is about 67 to 134 nm, and the average size and volume fraction of SiC particles are about 45 to 60 nm and 17.3 to 31.1% respectively.

Further, the SiC particles are mostly precipitated on the NbSi₂ grain boundary to suppress the growth of NbSi₂ grains, thereby enabling the manufacture of an equiaxed NbSi₂ coating with an average grain size of about 67 to 134 nm.

On the contrary, the conventional NbSi₂ coating layer manufactured by chemical vapor deposition has a columnar structure as shown in FIG. 1.

Especially, as a result of observing the surface of the NbSi₂—SiC nanocomposite coating layer according to Example 1 of the present invention by an optical microscope and calculating the crack density (the number of cracks per unit length of linear inspection on the cross-section) thereon, it can be seen that there is no crack formed at all, while the crack density of the conventional NbSi₂ coating layer has about 41 per cm. Consequently, it suggests that the thermal expansion coefficient of the NbSi₂—SiC nanocomposite coating layer in Example 1 is very similar to that of the Nb substrate.

### EXAMPLE 3

Niobium pretreated in the same manner as in Example 1 was put into a high purity alumina reaction tube capable of chemical vapor deposition of nitrogen, a high purity argon gas (99.9999%) was blown thereinto to remove oxygen in the reaction tube, heated up to 800 to 1500° C. at a heating rate of 5 to 20° C./min while flowing a high purity argon gas at a flow rate of 100 to 2,000 cm/min, then preserved for about 10 to 20 minutes in order to stabilize a deposition temperature, and then nitrogen was deposited on the niobium metal surface for 10 minutes to 200 hours while supplying a nitrogen gas at a flow rate of 3 to 2,000 cm/min respectively.

The nitrogen deposited on the surface of the substrate chemically reacted with niobium to form two diffusion layers composed of NbN, Nb₄N₃ and Nb₂N, respectively. As the deposition time increases, the nitrogen deposited on the niobium metal surface diffuse to the interface between niobium nitride and niobium through the niobium nitride diffusion layers and then reacted with a new niobium to form the niobium nitride diffusion layers in proportion to the square root of the deposition time.

Accordingly, it is possible to kinetically calculate the deposition temperature and time for making a niobium nitride diffusion layers of a predetermined thickness. As an example, if nitrogen is chemically vapor-deposited for about 8 hours at a deposition temperature of 1300° C., a Nb₂N diffusion layer having a thickness of approximately 8 μm and a mixed diffusion layer of NbN and Nb₄N₃ phases having a thickness of approximately 10 μm grow on the niobium metal surface.

After manufacturing a niobium nitride diffusion layers with a predetermined thickness, the supplying of nitrogen gas was stopped, the niobium nitride diffusion layers was cooled down to 1100° C. at a cooling rate of 5° C./mm while supplying a high purity argon gas into the reaction tube at a flow rate of 30 to 3,000 cm/min, and then silicon was chemically vapor-deposited on the surface of the niobium nitride diffusion layers for 30 minutes to 30 hours while supplying a silicon tetrachloride gas and hydrogen into the reaction tube, with the flow ratio thereof set to about 0.005 to 0.5 and the total flow set to about 30 to 4,000 cm/min.

The deposited silicon formed an NbSi₂ phase and a Si₃N₄ phase by a solid-state displacement reaction with a niobium nitride phase. As the deposition time increased, the deposited silicon continued to diffuse inwardly through an NbSi₂—Si₃N₄ nanocomposite coating layer and reacts with the niobium nitride diffusion layers to form new NbSi₂ phase and Si₃N₄ particles, thereby manufacturing a NbSi₂—Si₃N₄ nanocomposite coating layer.

The thickness of the NbSi₂—Si₃N₄ nanocomposite coating layer grows in proportion to the square root of a vapor deposition time of silicon. Accordingly, it is possible to kinetically calculate the deposition temperature and time for making a NbSi₂—Si₃N₄ nanocomposite coating layer of a predetermined thickness. As an example, silicon is chemically vapor-deposited on the surface of the niobium nitride diffusion layers for 3 hours at a deposition temperature of 1100° C. and reactively diffused into the niobium carbide diffusion layers, thereby manufacturing a NbSi₂—Si₃N₄ nonocomposite coating layer having a thickness of 54 μm and excellent in oxidation resistance and corrosion resistance.

After the manufacture of the nanocomposite coating layer, it was furnace-cooled while flowing a high purity argon gas at a flow rate of 100 to 2,000 cm/min.

On the other hand, unlike the deposition of Si by chemical vapor deposition according to Example 3, a niobium substrate coated with a niobium nitride diffusion layers with a predetermined thickness is buried in a mixed powders composed of (1-70) wt % Si/(1-10) wt % NaF/(20-98) wt Al₂O₃ and then undergoes a pack siliconizing treatment in the same manner as in Example 2, thereby manufacturing a NbSi₂—Si₃N₄ nanocomposite coating.

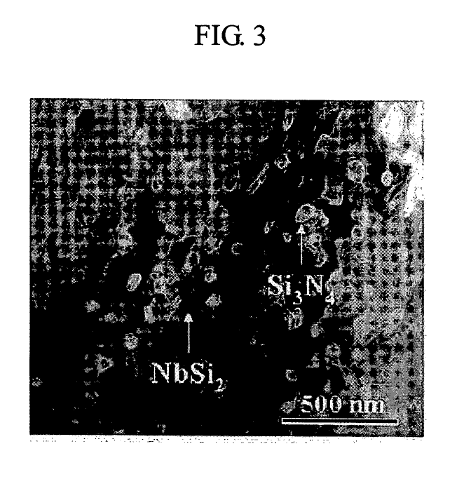

FIG. 3 is an optical micrograph of the cross-section of a NbSi₂—Si₃N₄ nanocomposite coating layer manufactured according to Example 3.

A comparison between the conventional NbSi₂ coating layer manufactured by chemical vapor deposition of silicon on a niobium substrate and the NbSi₂—Si₃N₄ nanocomposite coating layer according to Example 3 of the present invention is as follows.

The NbSi₂—Si₃N₄ nanocomposite coating layer according to Example 3, as shown in FIG. 3, has ultrafine Si₃N₄ particles formed on an equiaxed NbSi₂ grain boundary. By image analyzer, the average size of equiaxed NbSi₂ grain was measured as about 44 to 125 nm, and the average size and volume fraction of Si₃N₄ particles were about 33 to 45 nm and 16.8 to 24.4% respectively.

Further, the Si₃N₄ particles were mainly formed on the NbSi₂ grain boundary to suppress the growth of NbSi₂ grains, thereby enabling the manufacture of an equiaxed NbSi₂ coating having an average grain size of about 44 to 125 nm.

Especially, as shown in FIG. 3, from the result of calculating the crack density (the number of cracks per unit length of linear inspection on the cross-section) on the surface of the NbSi₂—Si₃N₄ nanocomposite coating layer manufactured according to Example 1, it can be seen that there is no crack formed at all, while the conventional NbSi₂ coating has about 41 per cm. Consequently, it suggests that the thermal expansion coefficient of the NbSi₂—Si₃N₄ nanocomposite coating layer manufactured in Example 3 was very similar to that of the Nb substrate.

With respect to the NbSi₂—SiC and NbSi₂—Si₃N₄ coating layer according to Examples 1 to 3 and the conventional simple NbSi₂ coating layer, the high-temperature isothermal oxidation resistance at 1100° C. is comparatively evaluated as follows.

### COMPARATIVE EXAMPLE

Preparing a niobium sample coated with a monolithic NbSi₂ with a thickness of about 60 μm, a niobium sample with a NbSi₂—SiC nanocomposite coating layer with a thickness of 50 μm according to Example 1 and a niobium sample with a NbSi₂—Si₃N₄ nanocomposite coating layer with a thickness of 50 μm according to in Example 3, the following oxidation resistance of the samples was tested at 1100° C. under a 80% Ar-20% O₂ atmosphere.

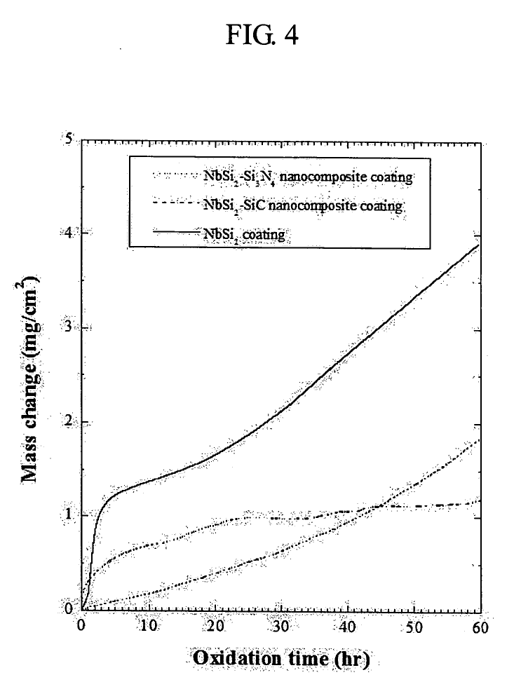

The high-temperature isothermal oxidation resistance was tested using a thermogravimetric analyzer (ThermoCahn 700). The respective samples were put onto a quartz tube boat, and were heated up to 1100° C. at a heating rate of 15° C./min under a high purity argon atmosphere. Then, the variation of the mass change per unit area of the samples under a 80% Ar-20% O₂ atmosphere with the oxidation time was observed. The results thereof as shown in FIG. 4. mean that the isothermal oxidation resistance of NbSi₂—Si₃N₄ nanocomposite coating layer is most excellent and that NbSi₂—SiC nanocomposite coating layer is more excellent in the oxidation resistance than monolithic NbSi₂ coating layer. Accordingly, it can be seen that the NbSi₂-base nanocomposite coating layer in accordance with the present invention is remarkably improved in the high-temperature oxidation resistance in comparison with the monolithic NbSi₂ coating layer.

According to the present invention, it is possible to provide the method of manufacturing NbSi₂—SiC and NbSi₂—Si₃N₄ nanocomposite coating layers by using chemical vapor deposition and pack siliconizing process which are advantageous in that the manufacturing process of a coating is simple and economical.

By adjusting the volume percentage of SiC or Si₃N₄ particles formed in the NbSi₂—SiC and NbSi₂—Si₃N₄ nanocomposite coating layers, respectively, the mismatch in the thermal expansion coefficient between the nanocomposite coating layer and the substrate is reduced. Therefore, the formation of fine cracks in the nanocomposite coating layers can be suppressed or completely eliminated, thereby improving high-temperature oxidation resistance. In addition, the increase in the volume fraction of dense SiO₂ oxide phase in the oxide layer formed in reaction with oxygen at high temperature improves the high-temperature oxidation resistance. Further, fine NbSi₂ grains improve the mechanical properties of the coating layer (the growth of fine cracks due to thermal stress can suppressed).

What is claimed is:

1. A NbSi₂-base nanocomposite, comprising:
a substrate selected from niobium or niobium-base alloys; and
a coating layer on the surface of the substrate, said coating layer having a microstructure that SiC particles are mostly precipitated on an equiaxed NbSi₂ grain boundary.

2. A NbSi₂-base nanocomposite, comprising:
a substrate selected from niobium or niobium-base alloys; and
a coating layer on the surface of the substrate, said coating layer having a microstructure that Si₃N₄ particles are mostly precipitated on an equiaxed NbSi₂ grain boundary.

3. A manufacturing method of an NbSi₂—SiC nanocomposite coating, comprising:
depositing carbon on the surface of niobium or niobium-base alloys to form a niobium carbide diffusion layers; and
depositing silicon on the surface of the niobium carbide diffusion layers to form a NbSi₂—SiC nanocomposite coating layer on the surface.

4. The method of claim 3, wherein a source of said carbon is one selected from the group consisting of carbon monoxide (CO), methane (CH₄), ethane (C₂H₄) and methylene iodide (CH₂I₂).

5. The method of claim 3, wherein a source of said silicon is one selected from the group consisting of SiCl₄, SiH₂Cl₂, SiH₃Cl and SiH₄.

6. The method of claim 3, wherein a source of said silicon is pack siliconizing powders composed of (1-70) wt % Si/(1-10) wt % NaF/(20-98) wt Al₂O₃.

7. A manufacturing method of an NbSi₂—Si₃N₄ nanocomposite coating, comprising:
depositing nitrogen on the surface of niobium or niobium-base alloys to form a niobium nitride diffusion layers; and
depositing silicon on the surface of the niobium nitride diffusion layers to form a NbSi₂—Si₃N₄ nanocomposite coating layer on the surface.

8. The method of claim 7, wherein a source of nitrogen is ammonia or nitrogen.

9. The method of claim 7, wherein a source of said silicon is one selected from the group consisting of SiC₄, SiH₂Cl₂, SiH₃Cl and SiH₄.

10. The method of claim 7, wherein a source of said silicon is pack siliconizing powders composed of (1-70) wt % Si/(1-10) wt % NaF/(20-98) wt Al₂O₃.
